(19) United States
(12) Patent Application Publication
(10) Pub. No.: US 2012/0141927 A1
(43) Pub. Date: Jun. 7, 2012

(54) REFLECTIVE MASK AND METHOD FOR MANUFACTURING THE SAME

(76) Inventor: Takashi KAMO, Yokohama-shi (JP)

(21) Appl. No.: 13/233,935

(22) Filed: Sep. 15, 2011

(30) Foreign Application Priority Data
Dec. 6, 2010 (JP) 2010-271506

(51) Int. Cl. G03F 1/00

(52) U.S. Cl. 430/5

(57) ABSTRACT

According to one embodiment, a method for manufacturing a reflective mask includes producing a reflective mask includes a substrate, a reflection layer provided on a front surface of the substrate and configured to reflect exposure light, an absorption layer provided on the reflection layer and configured to absorb the exposure light, and a conductive layer provided on a back surface of the substrate and held on an electrostatic chuck of an exposure apparatus, transferring a mask pattern of the reflective mask to a wafer, measuring misalignment between a basic pattern of the wafer and a transfer pattern transferred to the wafer, and recessing the conductive layer within a range smaller than a thickness of the conductive layer so as to reduce the misalignment.

### CROSS-REFERENCE TO RELATED APPLICATIONS

This application is based upon and claims the benefit of priority from prior Japanese Patent Application No. 2010-271506, filed Dec. 6, 2010, the entire contents of which are incorporated herein by reference.

### FIELD

Embodiments described herein relate generally to a reflective mask and a method for manufacturing the reflective mask.

### BACKGROUND

In recent years, with increasingly miniaturized semiconductor devices, EUV lithography, which is an exposure technique using extreme ultraviolet (EUV) light, has appeared promising. A reflective mask used for EUV lithography is held on an electrostatic chuck of an exposure apparatus to reflect exposure light. The exposure light reflected by the reflective mask allows a mask pattern to be transferred to a wafer.

During the exposure step of transferring the mask pattern to the wafer, the exposure light incident on the reflective mask obliquely enters the mask at a predetermined angle to the normal of the mask. Thus, transferring positional displacement may occur depending on the flatness or film thickness distribution of the reflective mask.

To suppress the transferring positional displacement, a technique to correct the position of the pattern in a mask drawing stage has been proposed. However, even when a reflective mask is produced with the position of the pattern corrected during mask drawing, systematic residual components may appear in addition to random residual components. The systematic residual components can be further subjected to positional correction so that mask drawing and production can be carried out again. However, this increases manufacturing costs for the mask and is expected to fail to meet a delivery date.

### BRIEF DESCRIPTION OF THE DRAWINGS

FIG. 1 is a cross-sectional view showing a configuration of a reflective mask 10;

FIG. 2 is a flowchart illustrating a method for manufacturing a reflective mask 10 according to a first embodiment;

FIGS. 3A and 3B are perspective views illustrating an example of flatness of a substrate 12 used for the reflective mask 10;

FIGS. 4A and 4B are schematic diagrams illustrating positional displacement of a mask pattern;

FIG. 5 is a diagram showing an example of a map for residual components of misalignment;

FIG. 6 is a diagram illustrating a to-be-processed area of a conductive layer 11;

FIG. 7 is a diagram illustrating the flatness of the reflective mask and positional displacement of the mask pattern;

FIG. 8 is a diagram illustrating the relationship between the film thickness distribution of the reflective mask 10 and transferring positional displacement;

FIG. 9 is a cross-sectional view illustrating the shape of a to-be-processed area 20 of the conductive layer 11;

FIGS. 10A, 10B, 10C and 10D are cross-sectional views showing a processing step for the conductive layer 11;

FIG. 11 is a diagram illustrating that the reflective mask 10 is held on an electrostatic chuck;

FIG. 12 is a diagram illustrating that the reflective mask 10 is held on the electrostatic chuck;

FIG. 13 is a flowchart illustrating a method for manufacturing the reflective mask 10 according to Example 1;

FIG. 14 is a flowchart illustrating a method for manufacturing the reflective mask 10 according to Example 2; and

FIG. 15 is a flowchart illustrating a method for manufacturing the reflective mask 10 according to a second embodiment.

### DETAILED DESCRIPTION

In general, according to one embodiment, there is provided a method for manufacturing a reflective mask, the method comprising:

producing a reflective mask comprising a substrate, a reflection layer provided on a front surface of the substrate and configured to reflect exposure light, an absorption layer provided on the reflection layer and configured to absorb the exposure light, and a conductive layer provided on a back surface of the substrate and held on an electrostatic chuck of an exposure apparatus;

transferring a mask pattern of the reflective mask to a wafer;

measuring misalignment between a basic pattern of the wafer and a transfer pattern transferred to the wafer; and

recessing the conductive layer within a range smaller than a thickness of the conductive layer so as to reduce the misalignment.

The embodiments will be described hereinafter with reference to the accompanying drawings. In the description which follows, the same or functionally equivalent elements are denoted by the same reference numerals, to thereby simplify the description.

### First Embodiment

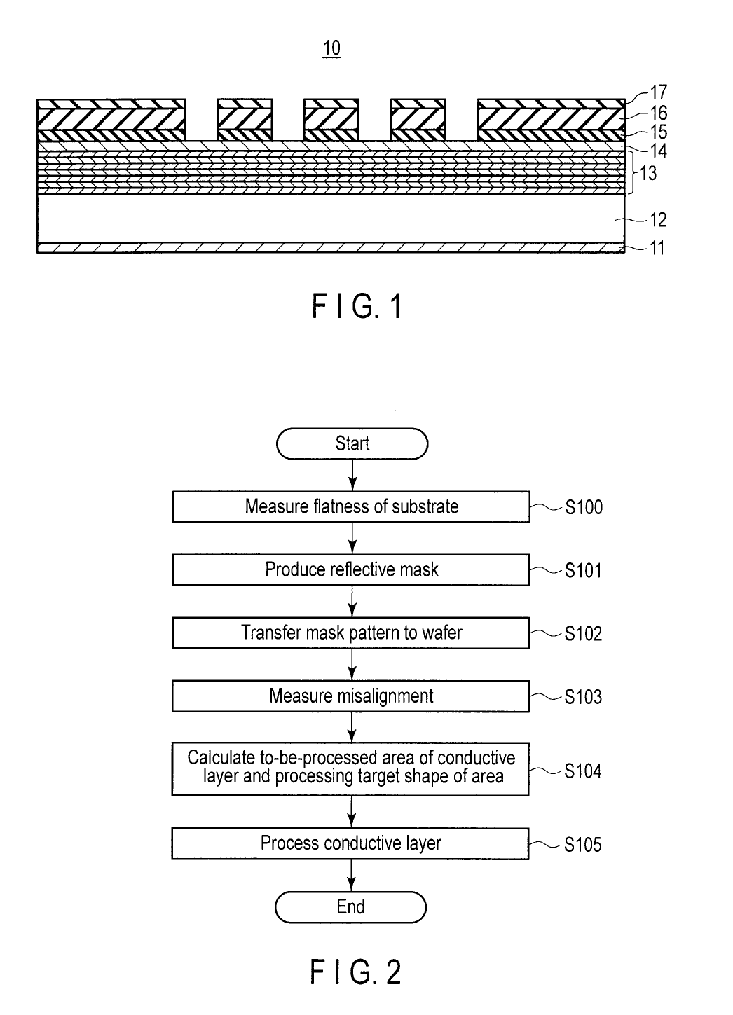

FIG. 1 is a cross-sectional view showing a configuration of the reflective mask 10 according to a first embodiment. A substrate 12 may be a glass substrate with a size of 6 inch×6 inch and with a very small coefficient of thermal expansion. A reflection layer 13 is provided on a front surface (principal surface) of the substrate 12 to reflect exposure light (EUV light). That is, the reflection layer 13 has a high reflectance with respect to the exposure light. The reflection layer 13 is formed of, for example, a stack film of about 40 pairs of silicon (Si) and molybdenum (Mo) alternately stacked therein.

A protect layer 13 is provided on the reflection layer 13 to protect an Mo film forming the reflection layer 13. For example, silicon (Si) is used as the protect film 14. A buffer film 15 is provided on the protect film 14 so as to serve as an etching stopper for formation of an absorption layer 16 or in order to avoid possible damage to the absorption layer when defects are eliminated. For example, chromium nitride (CrN) is used as the buffer layer 15.

The absorption layer 16 is provided on the buffer film 15. That is, the absorption layer 16 has a low reflectance with respect to the exposure light. For example, a nitride (TaBN) containing tantalum and boron is used as the absorption layer 16.

An antireflection layer 17 is provided on the absorption layer 16 to prevent reflection of inspection light of wavelength about 250 nm which is used to inspect the absorption layer 16 for a pattern. The antireflection layer 17 may be formed of a material with a sufficiently low reflectance with respect to the inspection light.

To provide the reflective mask 10 with a desired mask pattern, a lithography step and an etching step may be carried out to process the absorption layer 16 into a shape corresponding to a desired circuit pattern. This results in a reflective mask 10 with a mask pattern used to transfer the desired circuit pattern by exposure.

A conductive layer 11 is provided on a back surface of the substrate 12 to fix the reflective mask 10 to an electrostatic chuck of an exposure apparatus. For example, chromium nitride (CrN) is used as the conductive layer 11.

Now, a method for manufacturing the reflective mask 10 will be described. FIG. 2 is a flowchart illustrating a method for manufacturing the reflective mask 10.

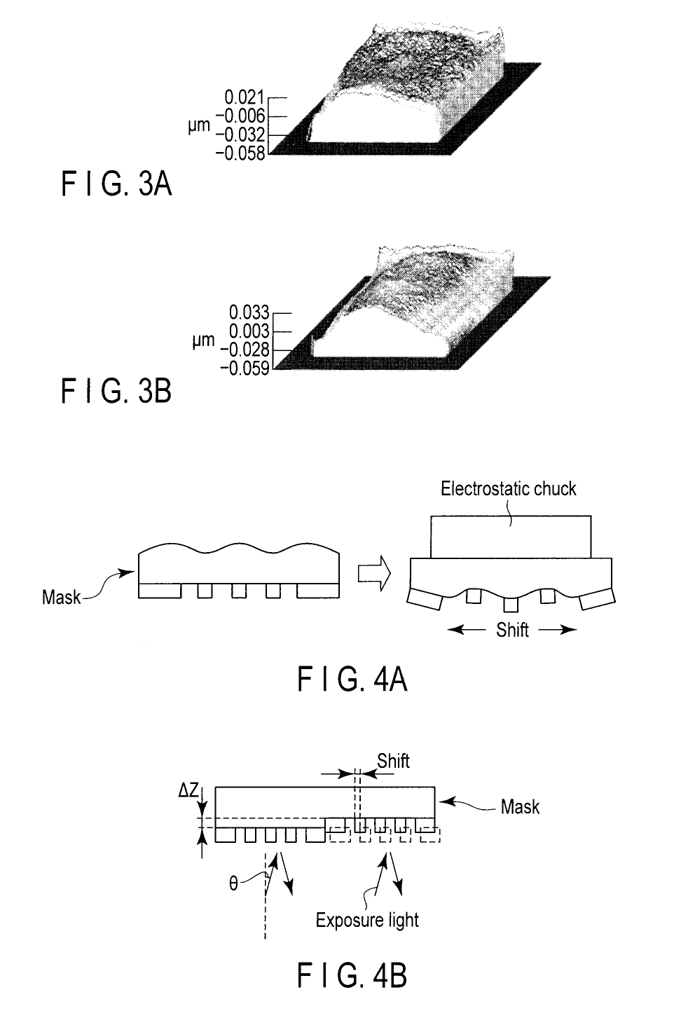

First, the substrate 12, used to produce a reflective mask 10, is prepared. Then, the flatness of the substrate 12 is measured (step S100). FIGS. 3A and 3B are perspective views illustrating an example of flatness of the substrate 12, used for the reflective mask 10. FIG. 3A is a diagram showing the front surface of the substrate 12. FIG. 3B is a diagram showing the back surface of the substrate 12. On the front surface of the substrate 12, the difference between the maximum height and the minimum height is about 79 nm (the difference is referred to as flatness data). On the back surface of the substrate 12, the flatness data is about 82 nm.

The reflective mask 10 is fixed to the electrostatic chuck of the exposure apparatus when the conductive layer 11 adheres to the electrostatic chuck. Thus, when the substrate 12 has a low flatness, positional displacement of the mask pattern may result from recesses and projections on the back surface of the reflective mask 10 or transferring positional displacement of the mask pattern may occur in connection with the film thickness distribution of the reflective mask 10. In the present embodiment, a high flatness means closeness to flatness, that is, corresponds to small flatness data. A low flatness means reduced flatness, that is, corresponds to great flatness data.

FIG. 4A is a schematic diagram illustrating positional displacement of the mask pattern resulting from recesses and projections on the back surface of the reflective mask. The reflective mask includes the recesses and projections on the back surface thereof. When the reflective mask adheres to the electrostatic chuck, the mask pattern on the front surface of the reflective mask shifts significantly from the original position thereof as a result of the recesses and projections on the back surface of the reflective mask.

FIG. 4B is a schematic diagram illustrating transferring positional displacement that occurs in connection with the film thickness distribution of the reflective mask. During an exposure step, exposure is obliquely incident on the reflective mask at a predetermined angle θ to the normal of the front surface of the reflective mask. A difference ΔZ in the film thickness of the reflective mask causes the mask pattern of the reflective mask to be transferred to the wafer so as to be shifted as is the case with a mask pattern shown by a dashed line in FIG. 4B.

Subsequently, a reflective mask 10 (FIG. 1) is produced which is subjected to position correction drawing based on a flatness measured value in order to reduce misalignment that occurs in connection with the flatness and film thickness distribution of the substrate 12 (step S101). That is, the reflective mask 10 produced in step S101 is corrected for the misalignment that occurs in connection with the flatness and film thickness distribution of the substrate 12.

Subsequently, a wafer is prepared with a basic pattern already formed using an exposure apparatus (for example, an ArF scan exposure apparatus). Then, the reflective mask 10 is held on the electrostatic chuck of an EUV exposure apparatus. The mask pattern of the reflective mask 10 is then transferred to the wafer (step S102). Specifically, a processing target film to be processed is formed on the basic pattern of the wafer, and a resist is coated on the wafer and then exposed and developed using the reflective mask 10. Subsequently, the processing target film is etched through the developed resist pattern as a mask. Thereafter, the resist is removed. Thus, the mask pattern of the reflective mask 10 is transferred to the processing target film of the wafer.

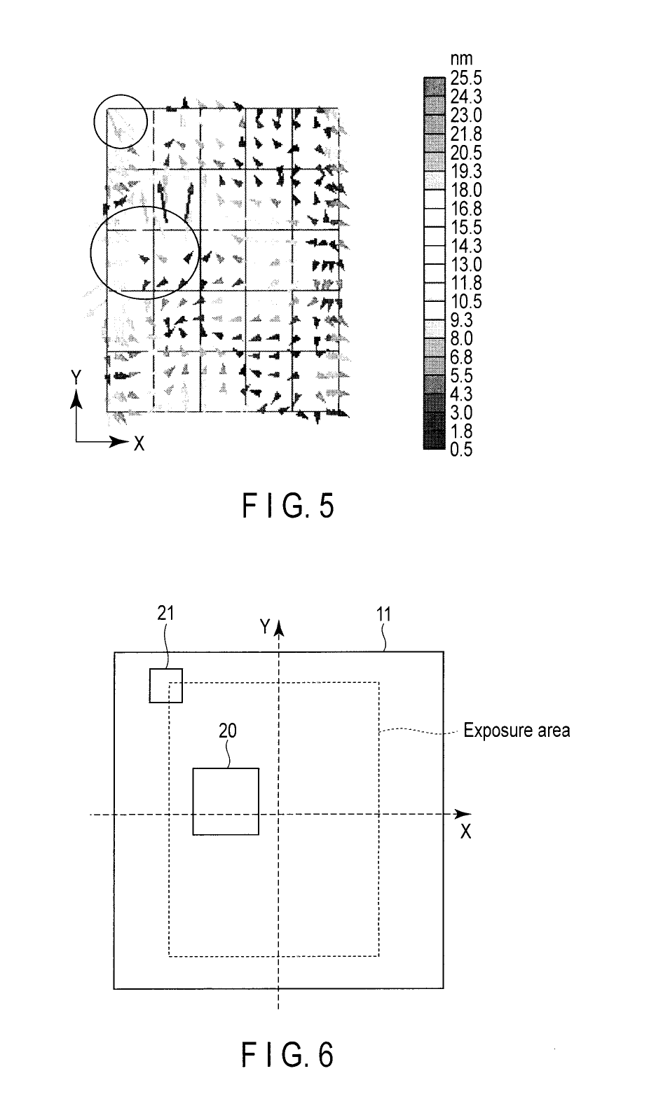

Subsequently, misalignment is measured using the transfer pattern transferred to the wafer and the basic pattern preformed on the wafer (step S103). FIG. 5 is an example of a map for residual components of misalignment. In FIG. 5, the magnitudes and directions of residuals are expressed by vectors. The length of each of the vectors increases consistently with the magnitude of misalignment. In FIG. 5, the average value of residuals is zero in an X-direction and a Y-direction. In the X-direction, 3σ (3σX)=17.4 nm. In the Y-direction, 3σ (3σY)=19.7 nm. An outer frame in FIG. 5 corresponds to an exposure area.

In step S101, when the reflective mask 10 is produced, transferring position displacement that occurs in connection with the flatness and film thickness distribution of the substrate 12 is taken into account. Thus, misalignment is essentially minimized. However, in actuality, FIG. 5 shows that significant misalignment has occurred at some positions as a result of systematic residual components. The systematic residual components correspond to misalignment that occurs in connection with the exposure apparatus. Specifically, the systematic residual components include elapsed staining of the electrostatic chuck and a variation in the flatness of the front surface of the electrostatic chuck due to abrasion. In FIG. 5, two encircled areas indicate that misalignment of for example, at least 15 nm has occurred in these areas.

Subsequently, the to-be-recessed area of the conductive layer 11 on the back surface of the substrate 12 as well as the processing target shape of the area are calculated such that the misalignment obtained in step S103 is set to at most a given value (within a predetermined allowable range) (step S104). In the present embodiment, the predetermined allowable range is, for example, 15 nm. FIG. 6 illustrates a to-be-processed area of the conductive layer 11. FIG. 6 shows that the substrate lies with the back surface of the reflective mask 10 facing upward. The positions and sizes of to-be-processed areas 20 and 21 of the conductive layer 11 are calculated from FIG. 5. Misalignment of greater than 15 nm occurs in the to-be-processed areas 20 and 21.

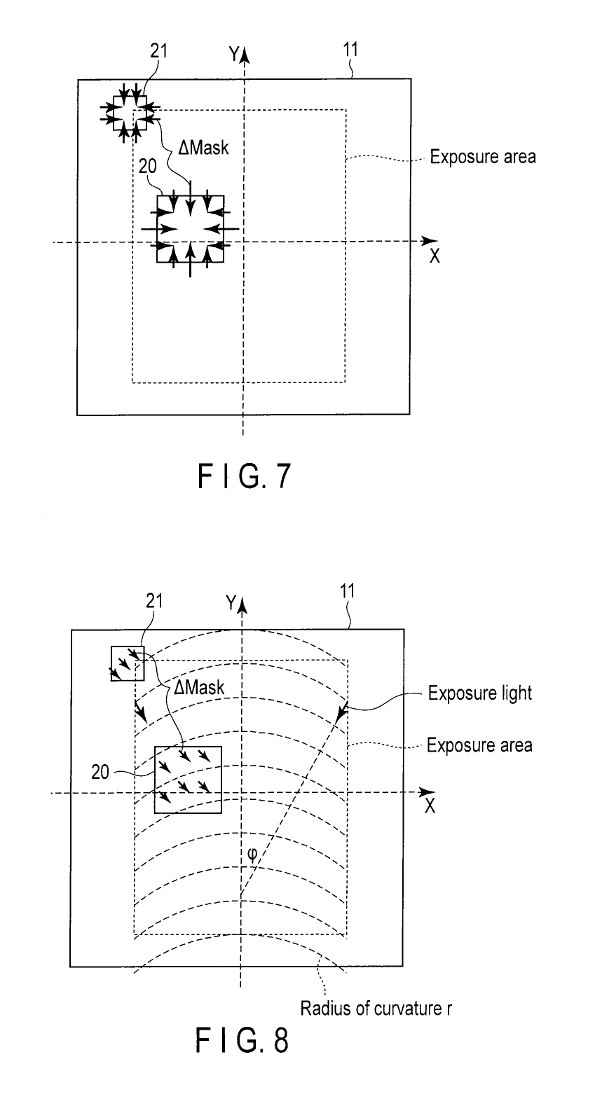

FIG. 7 is a diagram illustrating positional displacement of a mask pattern that occurs when the conductive layer 11 adheres to a flat electrostatic chuck. The following expression indicates the amount ΔMask by which the mask pattern of the reflective mask (the pattern of the absorption layer 16) is shifted depending on the flatness of the conductive layer 11 when the conductive layer 11 adheres to the electrostatic chuck.

ΔMask=(dz/dx, dz/dy)×t/2

In the expression, t denotes the film thickness of the reflective mask 10 and a normal direction on the front surface of the reflective mask 10 is referred to as a Z-direction.

Furthermore, when the reduction ratio of a reduced projection optical system is denoted by mag, the amount ΔWafer by which the transfer pattern transferred to the wafer is shifted is expressed as follows.

ΔWafer=ΔMask×mag

In FIG. 7, if the conductive layer 11 adheres to the electrostatic chuck, the mask pattern of the reflective mask 10 is shifted by an amount corresponding to the direction and magnitude of the vector, depending on the flatness of the conductive layer 11.

FIG. 8 is a diagram illustrating the relationship between the film thickness distribution of the reflective mask 10 and the transferring positional displacement. The EUV exposure apparatus irradiates the reflective mask 10 with exposure light (EUV light) in circular arc form. Thus, with recesses and projections on the front surface of the reflective mask 10, possible transferring positional displacement depends on the angle at which the circular arc exposure light is applied. In FIG. 8, the exposure light is inclined upward at an angle θ (for example, 6 degrees) to the normal of the surface of the reflective mask 10. A plurality of circular arc dashed lines in FIG. 8 indicate how the reflective mask 10 is scanned by the exposure light.

The following expression indicates the amount ΔMask by which the mask pattern of the reflective mask 10 (the pattern of the absorption layer 16) is shifted depending on the flatness of the surface of the reflective mask 10 when the conductive layer 11 adheres to the electrostatic chuck.

ΔMask=(sin φ, cos φ)×ΔZ×tan θ

In the expression, the amount of change in the film thickness of the reflective mask 10 caused by recesses and projections on the reflective mask 10 is denoted by ΔZ, the radius of curvature of the circular arc is denoted by r, and sin φ=x/r.

An expression for ΔWafer is the same as that described for FIG. 7.

In FIG. 8, if the conductive layer 11 adheres to the electrostatic chuck, the mask pattern of the reflective mask 10 is transferred to the wafer so as to be shifted by an amount corresponding to the direction and magnitude of the vector, depending on the flatness of the conductive layer 11.

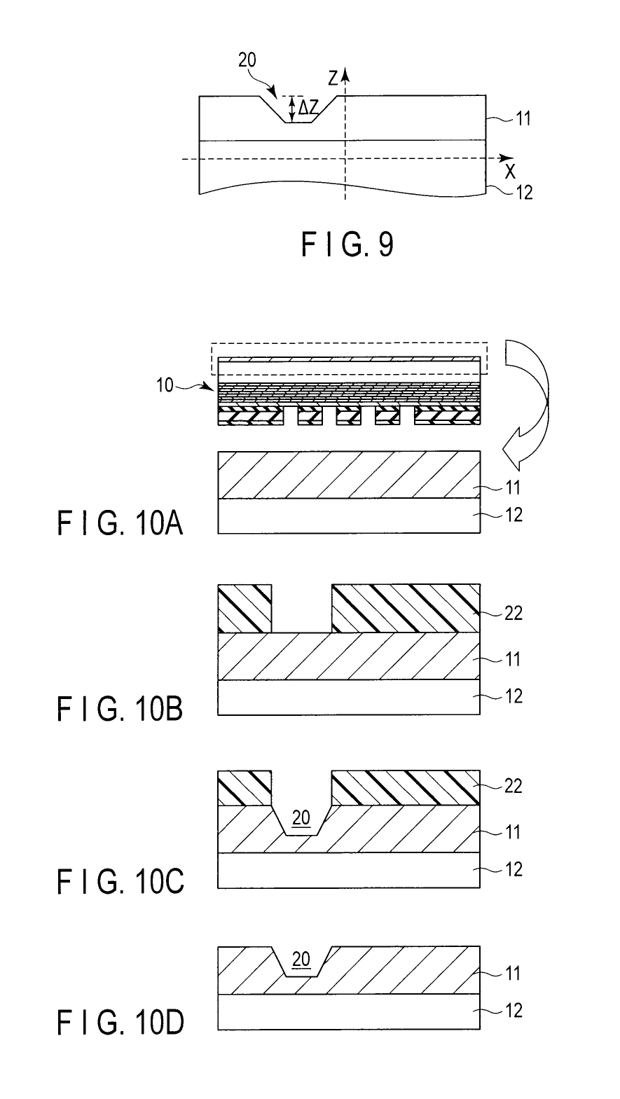

The sum of the vectors shown in each of FIGS. 7 and 8 corresponds to the amount by which positional displacement is corrected by processing the conductive layer 11. Thus, the optimum processing target shape (size and depth) of the conductive layer 11 are determined so as to minimize the sum of the misalignment obtained in FIG. 5 and the amount of positional displacement correction based on the processing of the conductive layer 11. FIG. 9 is a cross-sectional view illustrating the shape of the to-be-processed area 20 of the conductive layer 11.

Subsequently, the conductive layer 11 is recessed based on the results of the calculation in step S104 (step S105). A manufacturing operation in step S105 will be described below with reference to the drawings. First, as shown in FIG. 10A, the reflective mask 10 is prepared which is corrected for misalignment that occurs in connection with the flatness and film thickness distribution of the substrate 12 in step S101.

Subsequently, as shown in FIG. 10B, a resist 22 is coated on the cleaned conducive layer 11. Then, drawing data is created for the to-be-recessed area calculated in step S104. Based on the drawing data, the resist 22 is subjected to laser drawing and development. Thus, the resist 22 is formed on the conductive layer 11 so as to expose the to-be-processed area.

Subsequently, as shown in FIG. 10C, the conductive layer 11 is partly etched by a reactive ion etching (RIE) method using a mixed gas containing chloride and oxygen so that the range of etching is smaller than the film thickness. Here, the processing of the conductive layer 11 is stopped at the already calculated depth of the to-be-processed area. FIG. 10C shows the to-be-processed area 20 shown in FIG. 6. Subsequently, as shown in FIG. 10D, the resist 22 is stripped. As described above, the recess processing of the conductive layer 11 is completed.

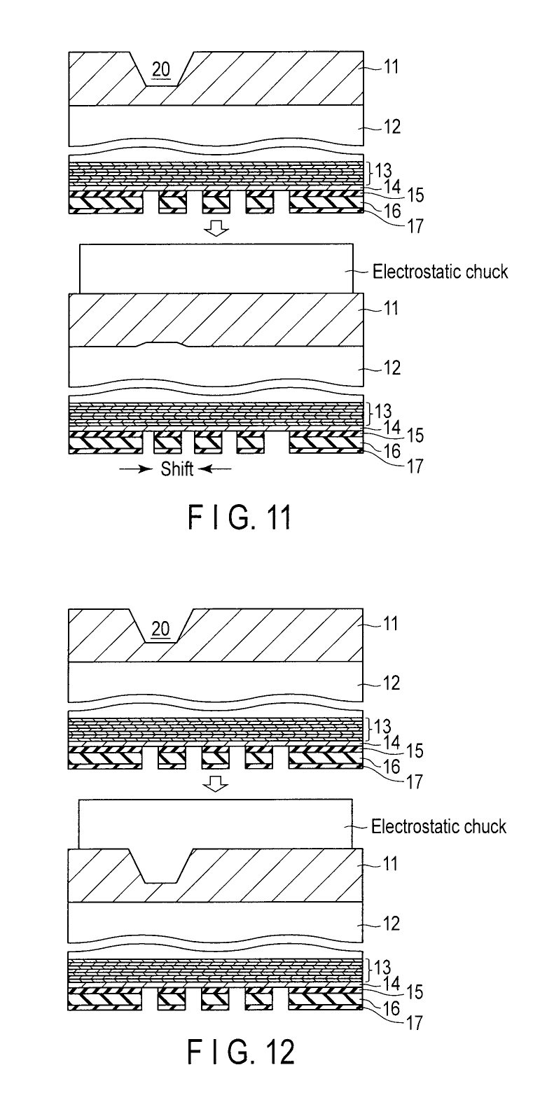

Thereafter, lithography is carried out using the reflective mask 10 with the recessed conductive layer 11. FIG. 11 shows that the reflective mask 10 with the recessed conductive layer 11 is held on the electrostatic chuck of the EUV exposure apparatus. In FIG. 11, the front surface (on which the reflective mask 10 is held) of the electrostatic chuck is, for example, flat. Furthermore, in FIG. 11, a part of the substrate 12 and the conductive layer are shown enlarged in the direction of the film thickness.

The to-be-processed area 20 of the conductive layer 11 adheres to the flat front surface of the electrostatic chuck. Thus, the mask pattern of the reflective mask 10 located opposite the to-be-processed area 20 is shifted toward the normal of the reflective mask 10. Hence, the position of the mask pattern can be shifted in the direction in which the residual components of misalignment occurred before the processing of the conductive layer 11 are cancelled.

Furthermore, if projecting foreign matter adheres to the front surface of the electrostatic chuck, the conductive layer 11 is recessed in the area corresponding to the projecting foreign matter as shown in FIG. 12. When the reflective mask 10 with the conductive layer 11 adheres to the electrostatic chuck, the reflective mask 10 can be restrained from being deformed. This enables a reduction in misalignment.

If desired alignment accuracy fails to be obtained during the first step of recessing the conductive layer 11, the whole conducive layer 11 is removed, and the back surface of the substrate 12 is cleaned. Subsequently, a new conductive layer 11 is deposited on the back surface of the substrate 12. Then, the conductive layer 11 may be recessed again.

### EXAMPLE 1

In the above description, the step of calculating the to-be-recessed area of the conductive layer 11 and the processing target shape of the area (step S104) uses the map for residual components of misalignment that occurs when the mask pattern of the reflective mask 10 is transferred to the wafer. In another example, after the reflective mask 10 is held on the electrostatic chuck, the flatness of the reflective mask 10 is measured. Then, the flatness obtained measured value of the reflective mask 10 obtained by the measuring step may be used to calculate the to-be-recessed area of the conductive layer 11 and the processing target shape of the area which are required to allow the reflective mask 10 to have an increased flatness after the reflective mask 10 is held on the electrostatic chuck.

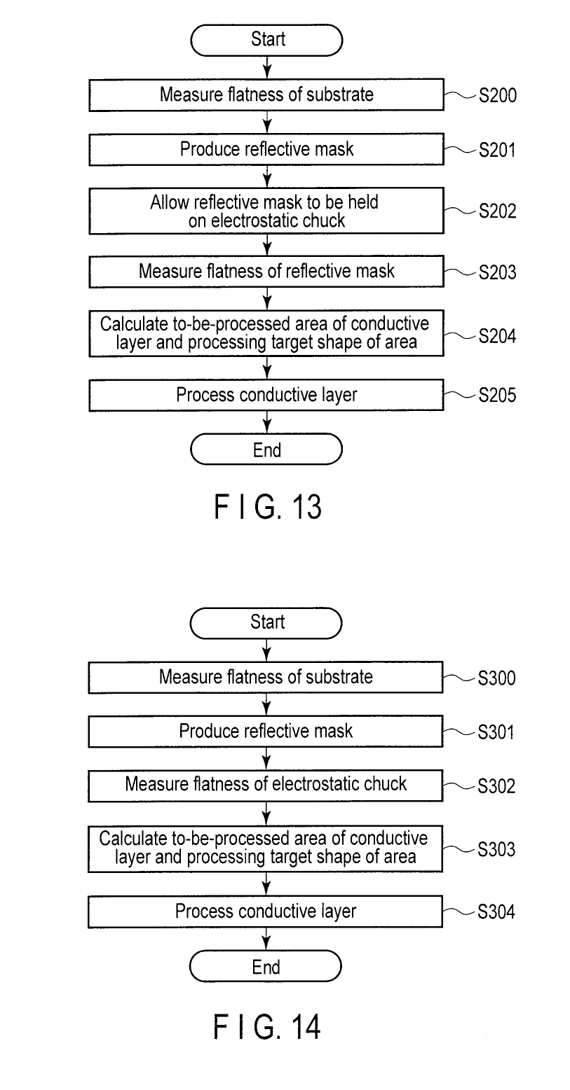

FIG. 13 is a flowchart illustrating a method for manufacturing the reflective mask 10 according to Example 1. Steps S200 and S201 are the same as steps S100 and S101 in FIG. 2.

Subsequently, the reflective mask 10 produced in step S201 is held on the electrostatic chuck of the EUV exposure apparatus (step S202). That is, the conductive layer 11 of the reflective mask 10 adheres to the electrostatic chuck.

Subsequently, with the reflective mask 10 held on the electrostatic chuck, the flatness of the front surface (located opposite the conductive layer 11) of the refection mask 10 is measured (step S203). This measurement step uses a measurement apparatus provided in the EUV exposure apparatus.

Subsequently, the to-be-recessed area of the conductive layer 11 and the processing target shape of the area is calculated using the measured value of flatness obtained in step S203 such that flatness of the reflective mask 10 increases after the reflective mask 10 is held on the electrostatic chuck (step S204). In step S204, the to-be-processed area is calculated to be the area for which the measured value of flatness exceeds a predetermined allowable range. The method for calculating the to-be-processed area and the processing target area is the same as that in step S104. Thereafter, the conductive layer 11 is recessed as in the case of step S105 (step S205).

In Example 1, the flatness of the reflective mask 10 held on the electrostatic chuck can be increased. This enables a reduction in misalignment that occurs in connection with the flatness of the reflective mask 10.

### EXAMPLE 2

In Example 2, an already measured flatness value of the electrostatic chuck is used to calculate the to-be-recessed area of the conductive layer 11 and the processing target shape of the area such that the flatness of the reflective mask 10 increases after the reflective mask 10 is held on the electrostatic chuck.

FIG. 14 is a flowchart illustrating a method for manufacturing the reflective mask 10 according to Example 2. Steps S300 and S301 are the same as steps S100 and S101 in FIG. 2.

Subsequently, the flatness of the electrostatic chuck of the EUV exposure apparatus is measured (step S302). If the measured value of flatness of the electrostatic chuck is already obtained, this data can be used.

Subsequently, the to-be-recessed area of the conductive layer 11 and the processing target shape of the area are calculated using the measured value of flatness obtained in step S303 such that misalignment that occurs in connection with the flatness of the electrostatic chuck reduces (step S303). In step S303, the to-be-processed area is calculated to be the area of the reflective mask 10, which contacts the area for which the measured value of flatness of the electrostatic chuck exceeds the predetermined allowable range. The method for calculating the to-be-processed area and the processing target area is the same as that in step S104. Thereafter, the conductive layer 11 is recessed as in the case of step S105 (step S304).

In Example 2, the flatness of the reflective mask 10 held on the electrostatic chuck can be increased. This enables a reduction in misalignment that occurs in connection with the flatness of the reflective mask 10.

### (Effects)

As described above in detail, in the first embodiment, the reflective mask 10 with the desired mask pattern is produced, and the mask pattern is transferred to the wafer using the reflective mask 10 and the exposure apparatus. Subsequently, misalignment is measured based on the transfer pattern transferred to the wafer and the basic pattern of the wafer. Then, the conductive layer 11 on the back surface of the reflective mask 10 is recessed so as to reduce misalignment.

Thus, the first embodiment enables a reduction in misalignment that occurs in connection with the exposure apparatus. Moreover, even if residual components of misalignment that occurs in connection with the flatness of the reflective mask 10 remain when the reflective mask 10 is produced, the residual components can be reduced by recessing the conductive layer 11. Thus, a wafer with a desired circuit pattern can be produced. Furthermore, the reflective mask 10 need not be produced again. Thus, the manufacturing costs of the reflective mask 10 can be reduced.

Furthermore, such a method as described in Example 1 may be used. That is, the flatness of the reflective mask 10 held on the electrostatic chuck is measured. Then, the obtained measured value of flatness is used to recess the conductive layer 11. Also in Example 1, the misalignment of the reflective mask can be reduced in the lithography step.

Additionally, the already measured flatness value of the electrostatic chuck may be used to recess the conductive layer 11 as in the case of Example 2. Also in Example 2, the misalignment of the reflective mask 10 can be reduced in the lithography step.

### Second Embodiment

In the steps of manufacturing a semiconductor device, one reflective mask may be used by plurality of EUV exposure apparatuses. In this case, data (the flatness of the electrostatic chuck and the like) relating to misalignment varies among the plurality of EUV exposure apparatuses. Thus, if the one reflective mask is used by the plurality of exposure apparatuses, misalignment may occur in some exposure apparatuses. In a second embodiment, even if a reflective mask subjected to positional correction intended for an exposure apparatus A is used in an exposure apparatus B, misalignment is reduced by recessing the conductive layer of the reflective mask.

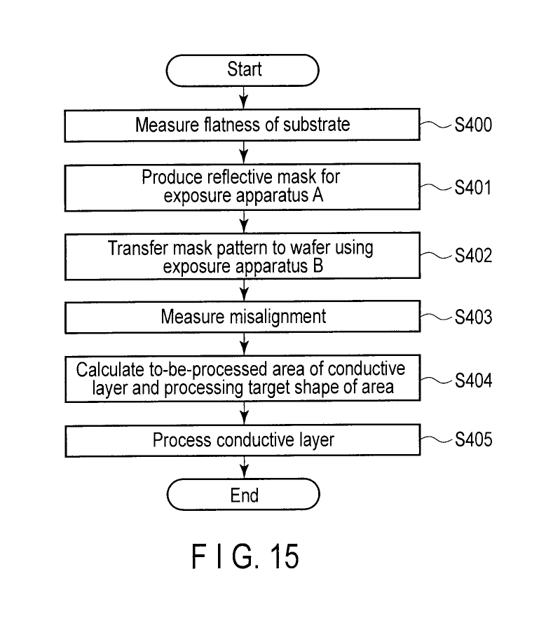

FIG. 15 is a flowchart illustrating a method for manufacturing the reflective mask 10 according to the second embodiment. First, the flatness of the substrate 12 used to produce the reflective mask 10 is measured (step S400).

Subsequently, the refection mask 10 is produced which is subjected to positional correction drawing based on the measured value of flatness obtained in step S400 and data relating to the misalignment of exposure apparatus A (step S401). Specifically, in the reflective mask 10 produced in step S401, the mask pattern is subjected to positional correction drawing so as to reduce misalignment that occurs in connection with the flatness and film thickness distribution of the substrate 12 and also to positional correction drawing so as to reduce misalignment that occurs in connection with the flatness of the electrostatic chuck of exposure apparatus A. This enables a reduction in misalignment if the reflective mask 10 is used for exposure apparatus A.

Subsequently, a wafer is prepared on which a basic pattern has already been formed using an exposure apparatus (for example, an ArF scan exposure apparatus). Then, the reflection chuck 10 is held on the electrostatic chuck of exposure apparatus B, which is different from exposure apparatus A. The mask pattern of the reflective mask 10 is then transferred to the wafer (step S402). Specifically, a processing target film to be processed is formed on the basic pattern of the wafer, and a resist is coated on the wafer and exposed and developed using the reflective mask 10. Then, the processing target film is etched through the developed resist pattern as a mask. Thereafter, the resist is removed. Thus, the mask pattern of the reflective mask 10 is transferred to the processing target film of the wafer.

Subsequently, as in the case of step S103, misalignment is measured using the transfer pattern transferred to the wafer and the basic pattern preformed on the wafer (step S403). The subsequent steps S404 and S405 are the same as steps S104 and S105 in the first embodiment. Thus, the reflective mask 10 can be produced which enables a reduction in misalignment in exposure apparatus B.

Furthermore, as in the case of Example 1, after the reflective mask 10 is held on the electrostatic chuck in the exposure apparatus, the flatness of the reflective mask 10 is measured. Then, the obtained measured value of flatness is used to calculate the to-be-recessed area of the conductive layer 11 and the processing target shape of the area which are required to allow the reflective mask 10 to have an increased flatness after the reflective mask 10 is held on the electrostatic chuck.

Furthermore, as in the case of Example 2, the pre-measured value of flatness of the electrostatic chuck of exposure apparatus B is used to calculate the to-be-recessed area of the conductive layer 11 and the processing target shape of the area which are required to allow the reflective mask 10 to have an increased flatness after the reflective mask 10 is held on the electrostatic chuck.

As described above, according to the second embodiment, even when the in-plane distribution tendency of misalignment accuracy changes as a result of the use of the reflective mask 10 for a plurality of exposure apparatuses, recessing the conductive layer 11 enables a reduction in misalignment even if any of the exposure apparatuses is used. The other effects of the second embodiment are the same as those of the first embodiment.

In each of the above-described embodiment, silicon (Si) is adopted as the protect film 14, and chromium nitride (CrN) is adopted as the buffer film 15. However, instead of these two layers, a material mainly comprising ruthenium (Ru) and serving both as the protect film and as the buffer film can be adopted. Furthermore, in the above-described embodiments, the reflective mask adopted comprises the antireflection layer 17 provided on the absorption layer 16 and used for mask defect inspection using deep ultraviolet (DUV) light. However, if an inspection apparatus using an electron beam (EB) is used as a mask defect inspection apparatus, the antireflection layer 17 is not necessarily required.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a reflective mask, the method comprising:
producing a reflective mask comprising a substrate, a reflection layer provided on a front surface of the substrate and configured to reflect exposure light, an absorption layer provided on the reflection layer and configured to absorb the exposure light, and a conductive layer provided on a back surface of the substrate and held on an electrostatic chuck of an exposure apparatus;
transferring a mask pattern of the reflective mask to a wafer;
measuring misalignment between a basic pattern of the wafer and a transfer pattern transferred to the wafer; and
recessing the conductive layer within a range smaller than a thickness of the conductive layer so as to reduce the misalignment.

2. The method of claim 1, wherein the recessing comprises:
calculating a to-be-processed area of the conductive layer so as to set the misalignment within a predetermined range; and
partly etching the calculated area.

3. The method of claim 1, wherein the recessing comprises:
forming a resist exposing a to-be-processed area on the conductive layer; and
etching the conductive layer using the resist as a mask.

4. The method of claim 1, further comprising:
measuring flatness of the substrate; and
correcting the mask pattern using the flatness of the substrate.

5. The method of claim 1, wherein the measuring comprises measuring misalignment that occurs due to flatness of the electrostatic chuck.

6. The method of claim 1, further comprising:
removing the conductive layer;
forming a conductive layer again on the back surface of the substrate; and
recessing the re-formed conductive layer.

7. A method for manufacturing a reflective mask, the method comprising:
producing a reflective mask comprising a substrate, a reflection layer provided on a front surface of the substrate and configured to reflect exposure light, an absorption layer provided on the reflection layer and configured to absorb the exposure light, and a conductive layer provided on a back surface of the substrate and held on an electrostatic chuck of an exposure apparatus;
allowing the reflective mask to be held on the electrostatic chuck;
measuring flatness of the reflective mask held on the electrostatic chuck; and
recessing the conductive layer within a range smaller than a thickness of the conductive layer so as to increase the flatness of the reflective mask.

8. The method of claim 7, wherein the recessing comprises:
calculating a to-be-processed area of the conductive layer such that the flatness of the reflective mask falls within a predetermined range; and
partly etching the calculated area.

9. The method of claim 7, wherein the recessing comprises:
forming a resist exposing a to-be-processed area on the conductive layer; and
etching the conductive layer using the resist as a mask.

10. The method of claim 7, further comprising:
measuring flatness of the substrate; and
correcting a mask pattern of the reflective mask using the flatness of the substrate.

11. The method of claim 7, wherein the flatness of the reflective mask changes depending on flatness of the electrostatic chuck.

12. The method of claim 7, further comprising:
removing the conductive layer;
forming a conductive layer again on the back surface of the substrate; and
recessing the re-formed conductive layer.

13. A method for manufacturing a reflective mask, the method comprising:
producing a reflective mask comprising a substrate, a reflection layer provided on a front surface of the substrate and configured to reflect exposure light, an absorption layer provided on the reflection layer and configured to absorb the exposure light, and a conductive layer provided on a back surface of the substrate and held on an electrostatic chuck of an exposure apparatus;
measuring flatness of the electrostatic chuck; and
recessing the conductive layer within a range smaller than a thickness of the conductive layer so as to increase flatness of the reflective mask held on the electrostatic chuck.

14. The method of claim 13, wherein the recessing comprises:
calculating a to-be-processed area of the conductive layer corresponding to an area for which the flatness of the electrostatic chuck exceeds a predetermined range when the reflective mask is held on the electrostatic chuck; and
partly etching the calculated area.

15. The method of claim 13, wherein the recessing comprises:
forming a resist exposing a to-be-processed area on the conductive layer; and
etching the conductive layer using the resist as a mask.

16. The method of claim 13, further comprising:
measuring flatness of the substrate; and
correcting the mask pattern using the flatness of the substrate.

17. The method of claim 13, wherein the flatness of the reflective mask changes depending on the flatness of the electrostatic chuck.

18. The method of claim 13, further comprising:
removing the conductive layer;
forming a conductive layer again on the back surface of the substrate; and
recessing the re-formed conductive layer.

19. A reflective mask manufactured by the manufacturing method according to claim 1.
